(19) United States
(12) Patent Application Publication
(10) Pub. No.: US 2025/0385116 A1
(43) Pub. Date: Dec. 18, 2025

(54) SUBSTRATE STORAGE SYSTEM AND CONTROL METHOD THEREOF

(71) Applicant: Samsung Electronics Co., Ltd., Suwon-si (KR)

(72) Inventors: Seong Sil JEONG, Suwon-si (KR); JIHUN KIM, Suwon-si (KR); SANGHYUK PARK, Suwon-si (KR)

(21) Appl. No.: 18/973,308

(22) Filed: Dec. 9, 2024

(30) Foreign Application Priority Data
Jun. 12, 2024 (KR) 10-2024-0076465

(51) Int. Cl. H01L 21/677

(52) U.S. Cl. CPC H01L 21/67769; H01L 21/6773; H01L 21/67736

(57) ABSTRACT

A substrate storage system includes a shelf assembly configured to accommodate a substrate receiving container, a container frame that supports the shelf assembly and includes an entrance corresponding to the shelf assembly, and a transport configured to move along a rail and configured to transfer the substrate receiving container into or from the shelf assembly, and the shelf assembly includes a link structure coupled to the container frame, and a shelf connected to the link structure, the transport includes a vehicle, a lift disposed below the vehicle, and a pressing arm disposed on the lift and configured to apply external force to the link structure, and the shelf is configured to move through the entrance of the container frame by moving as the link structure rotates.

### CROSS-REFERENCE TO RELATED APPLICATION

This application claims the benefit of Korean Patent Application No. 10-2024-0076465, filed on June 12, 2024, in the Korean Intellectual Property Office, the disclosure of which is incorporated herein by reference.

### BACKGROUND

### Field of the Invention

The present disclosure relates to a substrate storage system.

### Description of the Related Art

In order to store and transfer a substrate (e.g., a semiconductor wafer) in a production line for manufacturing a semiconductor device, a transfer device for transferring a carrier (e.g., a front opening unified pod (FOUP)) in which a plurality of substrates is received and a carrier storage equipment in which a plurality of carriers is stored are operated. The carrier storage equipment includes an individual storage space in which each of the carriers is stored and an interface port through which a carrier is loaded and unloaded. The transfer device is configured to load and unload the carrier through the interface port.

In such a carrier storage equipment in the related art, since multiple transfer devices perform a carrier loading and unloading task through the same interface port, there has been concern that a bottleneck phenomenon occurs in the interface port. Also, since an additional structure for transferring the carrier from the interface port to a carrier storage space and an additional space for installation thereof are required, the carrier storage equipment may become complicated and storage efficiency may be reduced.

### SUMMARY

An aspect of the invention provides a substrate storage system, which may increase efficiency of a loading and unloading process for a substrate receiving container, and a control method thereof.

Another aspect of the invention also provides a substrate storage system, which has a simple structure and may increase storage efficiency of a substrate receiving container, and a control method thereof.

However, the goals to be achieved by example embodiments of the present disclosure are not limited to the objectives described above and other objects may be clearly understood from the following example embodiments by those skilled in the art.

According to an aspect, a substrate storage system includes a shelf assembly configured to accommodate a substrate receiving container; a container frame that supports the shelf assembly and includes an entrance corresponding to the shelf assembly; and a transport configured to move along a rail disposed above the container frame, the transport being configured to load or unload the substrate receiving container into or from the shelf assembly, wherein the shelf assembly comprises: a link structure coupled to the container frame in a rotatable manner; and a shelf that is connected to the link structure and is configured to accommodate the substrate receiving container, wherein the transport comprises: a vehicle movably coupled to the rail; a lift disposed below the vehicle and configured to ascend and descend in a vertical direction; and a pressing arm disposed on the lift and configured to apply an external force to the link structure by moving in a direction toward the shelf assembly, and wherein the shelf is configured to move through the entrance of the container frame by moving as the link structure rotates, the rotation of the link structure being caused by the external force applied by the pressing arm.

According to another aspect, a control method of a substrate storage system includes lowering, from an initial position to a position next to a target shelf assembly selected from a plurality of shelf assemblies disposed in a container frame, a lift provided on a transport, the transport being configured to transfer a substrate receiving container to or from the container frame; withdrawing a shelf included in the target shelf assembly to an outside of the container frame by application, by a pressing arm disposed on the lift, of an external force to a link structure included in the target shelf assembly; and loading or unloading, with a grip connected to the lift, the substrate receiving container into or from the shelf.

According to still another aspect, a substrate storage system includes a container in which a plurality of shelf assemblies are arranged in a plurality of rows and columns, each of the plurality of shelf assemblies being configured to accommodate a substrate receiving container; and a transport configured to move alongside the container and configured to load and unload the substrate receiving container into and from a target shelf assembly selected from the plurality of shelf assemblies, wherein the transport comprises: a vehicle configured to move in a direction parallel to a row formed by the plurality of shelf assemblies; a lift connected with the vehicle and configured to move in a direction parallel to a column formed by the plurality of shelf assemblies; a latch disposed on the lift and configured to fix a position of the lift by engaging with the container; and a pressing arm disposed on the lift and configured to move a shelf of the target shelf assembly to an outside of the container by moving in a direction toward the target shelf assembly.

Additional aspects of example embodiments will be set forth in part in the description which follows and, in part, will be apparent from the description, or may be learned by practice of the disclosure.

According to example embodiments, a transportation device may directly load and unload a substrate receiving container into and from a shelf part provided in a storage space of a container. Accordingly, speed of a loading and unloading process and operation efficiency of a substrate storage system may be increased.

In addition, according to example embodiments, it is possible to provide a substrate storage system, which includes a container and a transportation device that have a simple structure and may achieve high storage efficiency, and a control method thereof.

Effects of the present disclosure are not limited to those described above and may vary within the scope of the technical spirit and extent of the present disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is an example perspective diagram illustrating a substrate storage system according to example embodiments;

FIG. 2 is an example cross-sectional diagram illustrating a substrate storage system according to example embodiments;

FIG. 3 is an enlarged diagram illustrating part A of FIG. 2;

FIG. 4 is a reference diagram for describing a link structure of a substrate storage system according to example embodiments;

FIG. 5 is a reference diagram illustrating a state in which an elastic member is connected to a link structure of a substrate storage system according to example embodiments;

FIGS. 6 through 9 are reference diagrams for describing an operation of a substrate storage system according to example embodiments; and

FIG. 10 is an example plan diagram illustrating a substrate storage system according to example embodiments.

### DETAILED DESCRIPTION

Before example embodiments are described, terms or words used in the present disclosure and the accompanying claims are not to be limited to general definitions or dictionary definitions. The terms and words are to be construed under a principle that an inventor may appropriately define a concept of a term in order to describe their invention in the best way. Thus, since the example embodiments described in the present disclosure and configurations illustrated in the accompanying drawings are merely desirable example embodiments and do not represent all of the technical spirit of the present disclosure, it should be understood that various equivalents and modifications that may replace the example embodiments and configurations may be present at the time of filing the application of the present disclosure.

In the following descriptions, terms in a singular form include terms in a plural form unless an apparently and contextually conflicting description is present. Terms such as "including" or "comprising" indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

In addition, it should be noted in advance that an expression such as an upper side, an upper portion, a lower side, a lower portion, a side surface, a front surface, or a rear surface is based on directions illustrated in the drawings and that the expression may be changed when a direction of a corresponding object is changed. Shapes, sizes, or the like of elements in the drawings may be exaggerated for clearer description.

Hereinafter, a substrate storage system according to the example embodiments will be described with reference to the drawings.

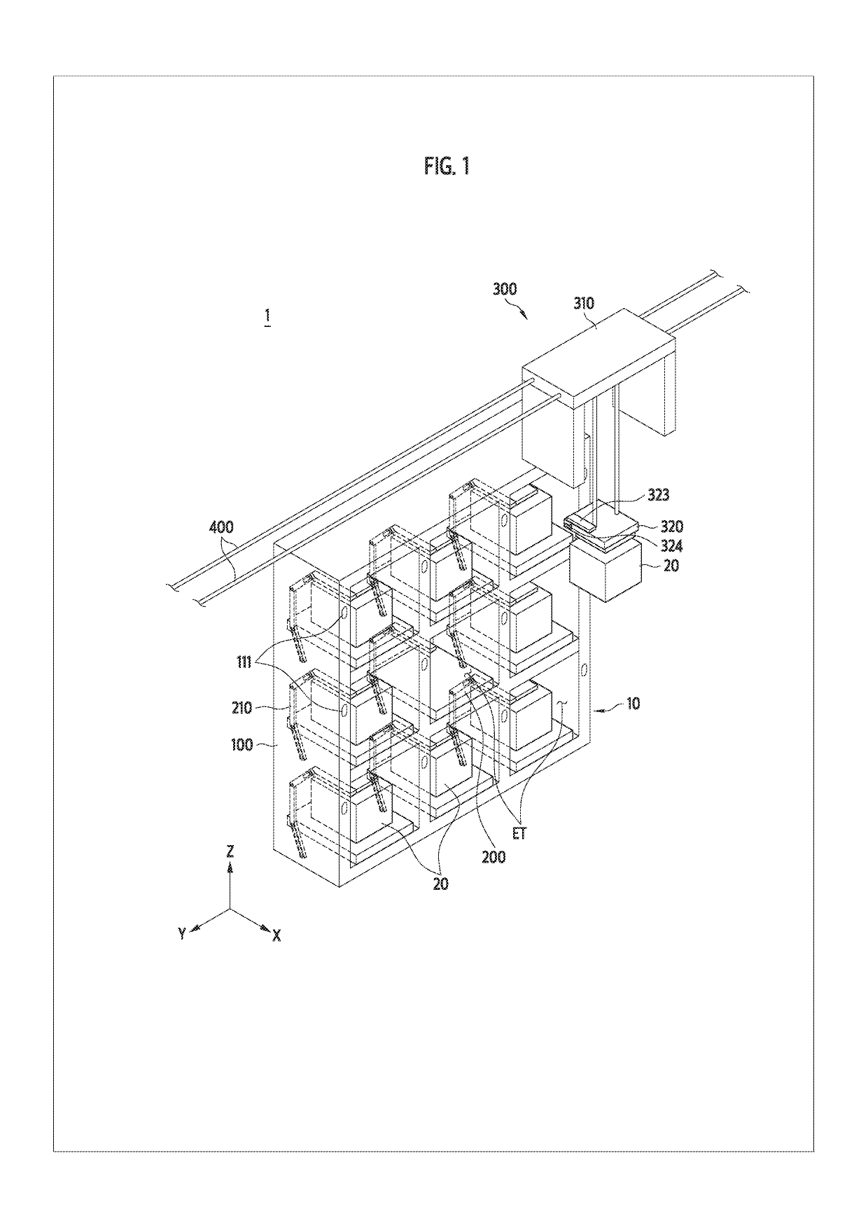

FIG. 1 is an example perspective diagram illustrating a substrate storage system 1 according to example embodiments.

The substrate storage system 1 according to example embodiments may be installed in a factory for semiconductor manufacture and configured to store a substrate receiving container 20 for receiving an article such as a semiconductor wafer or a reticle. The substrate receiving container 20 may be a member in various forms for receiving a substrate, such as a front opening unified pod (FOUP) or a front opening shipping box (FOSB).

In example embodiments, the substrate storage system 1 may include one or more containers 10 for storing multiple substrate receiving containers 20 and a transportation device 300 (e.g., a transport) for loading and unloading the substrate receiving container 20 into and from a container 10.

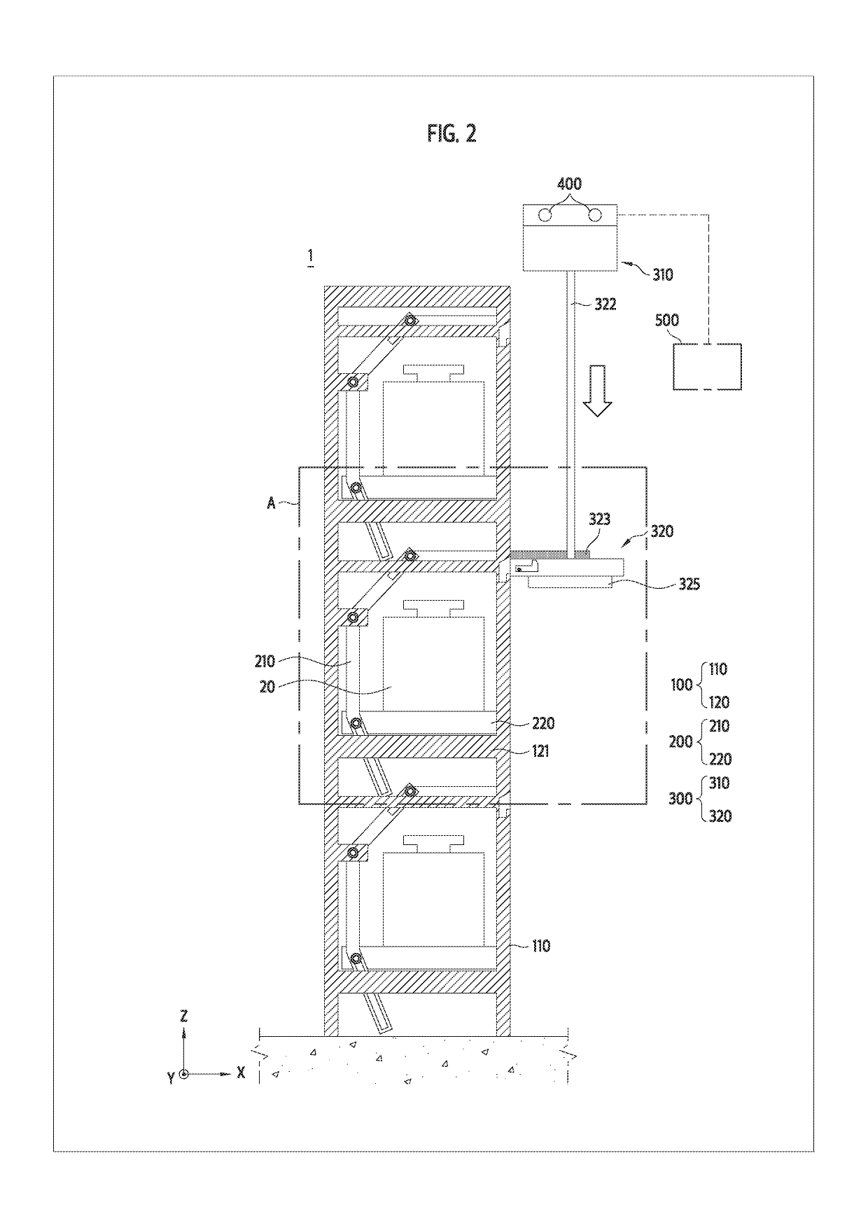

In example embodiments, the transportation device 300 may be configured to move along a rail 400 installed in the factory for semiconductor manufacture. According to control by a controller (e.g., a controller 500 in FIG. 2), the transportation device 300 may transfer the substrate receiving container 20 while moving among various workstations in the factory for semiconductor manufacture which includes the container 10. For example, the transportation device 300 may be at least a portion of an overhead hoist transport (OHT) system that is a logistics automation equipment for transferring an article while traveling along the rail 400 which is installed on a ceiling of the factory.

Although not illustrated, the controller 500 can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller 500 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

In example embodiments, a portion of the rail 400 which forms a movement path of the transportation device 300 may be disposed above the container 10. For example, referring to FIG. 1, the rail 400 may be disposed above a container frame 100 forming an outer shape of the container 10, and the transportation device 300 may load and unload the substrate receiving container 20 into and from the container 10 while moving along the rail 300.

In example embodiments, the transportation device 300 may include a traveling unit 310 (e.g., a vehicle) that travels along the rail 400 and a lifting unit 320 (e.g., a lift) that is connected with the traveling unit 310 and configured to move vertically to a desired point on the container 10.

In example embodiments, the container 10 may include the container frame 100 that forms the outer shape of the container 10 and a shelf assembly 200 that is supported by the container frame 100 and loaded with the substrate receiving container 20.

In example embodiments, the container frame 100 may be formed of a material having rigidity sufficient to stably support multiple shelf assemblies 200 and the multiple substrate receiving containers 20. For example, at least a portion of the container frame 100 may be formed of a metallic material such as iron or stainless steel.

In example embodiments, the container frame 100 may have a plurality of storage spaces divided from each other. A shelf assembly 200 which is loadable with the substrate receiving container 20 may be disposed in each of the storage spaces. The shelf assembly 200 is configured to move with respect to the container frame 100. A shelf part (e.g., a shelf) of the shelf assembly 200 may enter an inside of the container frame 100 or exit to an outside of the container frame 100 through an entrance ET provided on a side of a storage space being opened.

In example embodiments, movement of the shelf assembly 200 may be interlocked with the transportation device 300. For example, the shelf part of the shelf assembly 200 may be withdrawn to the outside of the container frame 100 or carried into the inside of the container frame 100 through the entrance ET by an operation of the transportation device 300.

In example embodiments, a plurality of shelf assemblies 200 may be arranged in a plurality of rows and columns in the container frame 100. For example, referring to FIG. 1, in the container frame 100, a plurality of shelf assemblies 200 may be arranged in a horizontal direction (e.g., a Y-axis direction) and a vertical direction (e.g., a Z-axis direction) to form the plurality of rows and columns. In the container frame 100, a plurality of entrances ET through which a shelf assembly 200 may enter and exit may be formed to correspond to respective positions of the shelf assemblies 200.

In example embodiments, the transportation device 300 may be configured to directly load and unload the substrate receiving container 20 into and from a shelf assembly to be loaded and unloaded with the substrate receiving container 20 (hereinafter referred to as a target shelf assembly) among the plurality of shelf assemblies 200. For example, referring to FIG. 1, the transportation device 300 may approach the target shelf assembly by using the traveling unit 310 which moves in a direction parallel to a row formed by the plurality of shelf assemblies 200 (e.g., the Y-axis direction) and the lifting unit 320 which moves in a direction parallel to a column formed by the plurality of shelf assemblies 200 (e.g., the Z-axis direction) and directly load and unload the substrate receiving container 20. To this end, the transportation device 300 may further include a pressurization part 323 (e.g., a pressing arm, see FIG. 2) for withdrawing a shelf part 200 (of FIG. 2) of a target shelf assembly 200 to the outside of the container frame 100 and a position fixation part 324 (e.g., a latch, see FIG. 2) for fixing a position of the lifting unit 320 so that an operation of loading and unloading the substrate receiving container 20 is stably performed.

Hereinafter, the substrate storage system 1 according to example embodiments will be described in more detail with reference to FIGS. 2 through 9.

Since the substrate storage system 1 which will be described in FIGS. 2 through 9 corresponds to the substrate storage system 1 which is described above in FIG. 1, redundant descriptions may be omitted.

FIG. 2 is an example cross-sectional diagram illustrating the substrate storage system 1 according to example embodiments.

In example embodiments, according to an order from the controller 500, the transportation device 300 may move among various workstations in a semiconductor manufacture factory, such as the container 10.

Referring to FIG. 2, the transportation device 300 may include the traveling unit 310 which may move along the rail 400 and the lifting unit 320 which is connected with the traveling unit 310 and may ascend and descend in a vertical direction (e.g., a Z-axis direction).

In example embodiments, the traveling unit 310 may be movably coupled to the rail 400 which is disposed close to the container frame 100. For example, referring to FIG. 2, the rail 400 may be disposed above the container frame 100 so that even an upper portion of the container 10 may be used as a loading space, and the traveling unit 310 may move in a sliding manner in an extension direction of the rail 400 (e.g., a Y-axis direction) in a state of being coupled to the rail 400. Although not illustrated in the drawings, the traveling unit 310 may further include a friction reduction member such as a roller or a bearing.

In example embodiments, the lifting unit 320 may be connected to the traveling unit 310 and configured to ascend and descend to a position opposite to the target shelf assembly 200 among the plurality of shelf assemblies 200. For example, the lifting unit 320 may be connected through a connection member 322 (e.g., a rod), and a motor and/or an actuator (not illustrated) provided to the transportation device 300 may move the lifting unit 320 in the vertical direction (e.g., the Z-axis direction in FIG. 2) by winding or unwinding the connection member 322. The connection member 322 may be provided as a pulley structure including a hoist member such as a belt, a wire, or a rope. However, a detailed structure or shape thereof is not limited thereto.

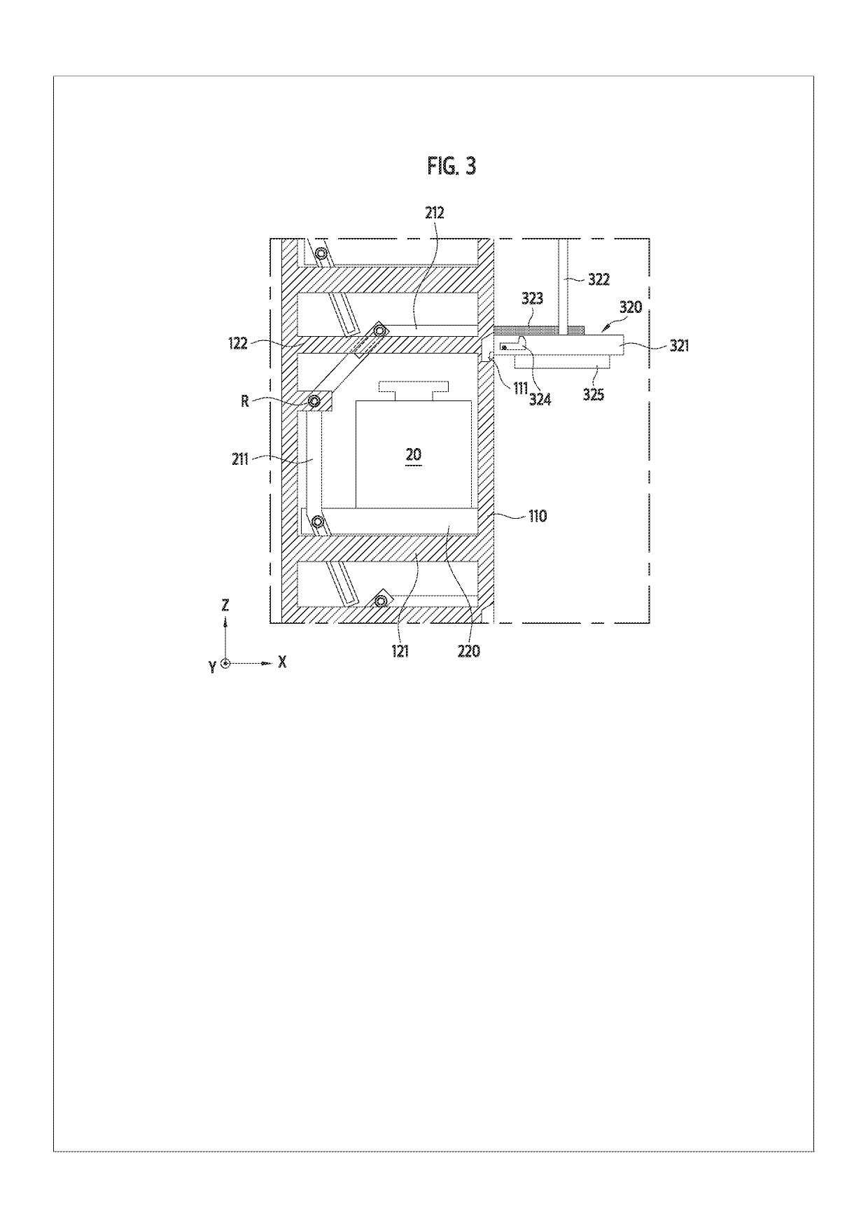

FIG. 3 is an enlarged diagram illustrating part A of FIG. 2.

Referring to FIG. 3, the lifting unit 320 may include a moving body part 321 (e.g., a body) connected to the connection member 322, the pressurization part 323 provided to the moving body part 321 to apply external force to the shelf assembly 200 of the container 10, and the position fixation part 324 which fixes a relative position of the moving body part 321 with respect to the container frame 100.

In example embodiments, the moving body part 321 may be connected to the connection member 322 to move to a position facing the target shelf assembly 200. For example, the controller 500 may determine a shelf assembly 200 that is to be loaded and unloaded with the substrate receiving container 20 (namely, a target shelf assembly) among the plurality of shelf assemblies 200 (of FIG.2), move the traveling unit 310 to a position corresponding to a column in which the target shelf assembly 200 is disposed, and then lower the moving body part 321 of the lifting unit 320 to the position facing the target shelf assembly 200 (e.g., to a position corresponding to a row in which the target shelf assembly 200 is disposed).

In example embodiments, the pressurization part 323 for withdrawing a shelf part 220 of the shelf assembly 200 may be disposed on the moving body part 321 of the lifting unit 320. The pressurization part 323 may move in a direction from the moving body part 321 toward the shelf assembly 200 (e.g., a negative direction of an X-axis in FIG. 2), push a link structure 210 (of FIG. 2) of the shelf assembly 200, and apply the external force to the link structure 210 thereby. Alternatively, at least a portion of the pressurization part 323 may elongate and contract in a horizontal direction (e.g., an X-axis direction in FIG. 2) so that the pressurization part 323 applies the external force to the link structure 210. The link structure 210 of the shelf assembly 200 may be caused to rotate by the external force applied as such by the pressurization part 323. Accordingly, the shelf part 220 which is connected to the link structure 210 may be withdrawn to an outside of the container frame 100. The pressurization part 323 may be, for example, a rod, a shaft, a plate, or any other member formed of a rigid material sufficient to cause the link structure 210 to move when applying an external force thereto.

In example embodiments, the pressurization part 323 may be configured to be driven in a sliding manner on the moving body part 321. For example, the pressurization part 323 may include a bar-shaped rigid body, an actuator (not illustrated) for moving the rigid body in a sliding manner, and a guide rail (not illustrated) for guiding movement of the rigid body. However, detailed configuration of the pressurization part 323 is not limited thereto. The pressurization part 323 may be formed as any structure that may apply the external force to the shelf assembly 200 by moving relatively with respect to the moving body part 321.

In example embodiments, the lifting unit 320 may further include a grip part 325 (e.g., a grip) for gripping the substrate receiving container 20. The grip part 325 may be connected to the moving body part 321 of the lifting unit 320. The grip part 325 may be configured to ascend and descend with respect to the moving body part 321. The grip part 325 may descend from the moving body part 321 in a state in which the shelf part 220 is withdrawn to the outside of the container frame 100 and may load the substrate receiving container 20 into the shelf part 220 or pick up the substrate receiving container 20 which is loaded into the shelf part 220.

In example embodiments, the lifting unit 320 may further include the position fixation part 324 for fixing a position of the moving body part 321 in a process of loading or unloading the substrate receiving container 20 or in a driving process for the pressurization part 323. For example, referring to FIGS. 2 and 3 together, the position fixation part 324 may be a hook-type member coupled to the moving body part 321 in a rotatable manner. To correspond thereto, a fixation groove 111 in which a hook portion of the moving body part 321 may be caught may be provided in the container frame 100. One or more fixation grooves 111 may be correspond to, and may be positioned next to, each of the entrances ET (of FIG. 1) of the container frame 100. As the fixation part 324 rotates to engage with the fixation groove 111 of the container frame 100 in a state in which the moving body part 321 is in the correct position (for example, at a position at which the pressurization part 323 disposed on the moving body part 321 and a lever part 212 (e.g., a lever) of the shelf assembly 200 face each other), the moving body part 321 may not move further relative to the container frame 100 and may be fixed to the container frame 100.

However, a detailed structure of the position fixation part 324 is not limited to the above description. For example, the position fixation part 324 may be provided as a magnet-type member (e.g., a magnet) movably coupled to the moving body part 321 and may fix the position of the moving body part 321 by moving toward and adhering to the container frame 100 in a state in which the moving body part 321 is in the correct position.

In example embodiments, a shelf assembly 200 may be disposed in each storage space provided in the container frame 100. For example, referring to FIGS. 2 and 3, the shelf assembly 200 may include the shelf part 220 which is configured to be loaded with the substrate receiving container 20 and the link structure 210 which is connected to the shelf part 220 and coupled to, in a rotatable manner, a rotation shaft R connected to the container frame 100.

In example embodiments, the link structure 210 may be configured to move the shelf part 220 to an inside or the outside of the container frame 100 by using the external force applied by the pressurization part 323 of the lifting unit 320. For example, the link structure 210 may move the shelf part 220 in a sliding manner by pushing or pulling the shelf part 220 in a process of rotating around the rotation shaft R by receiving the external force from the pressurization part 323 of the lifting unit 320. In other words, the link structure 210 may serve as a medium for sending the external force which is generated in the pressurization part 323 to the shelf part 220.

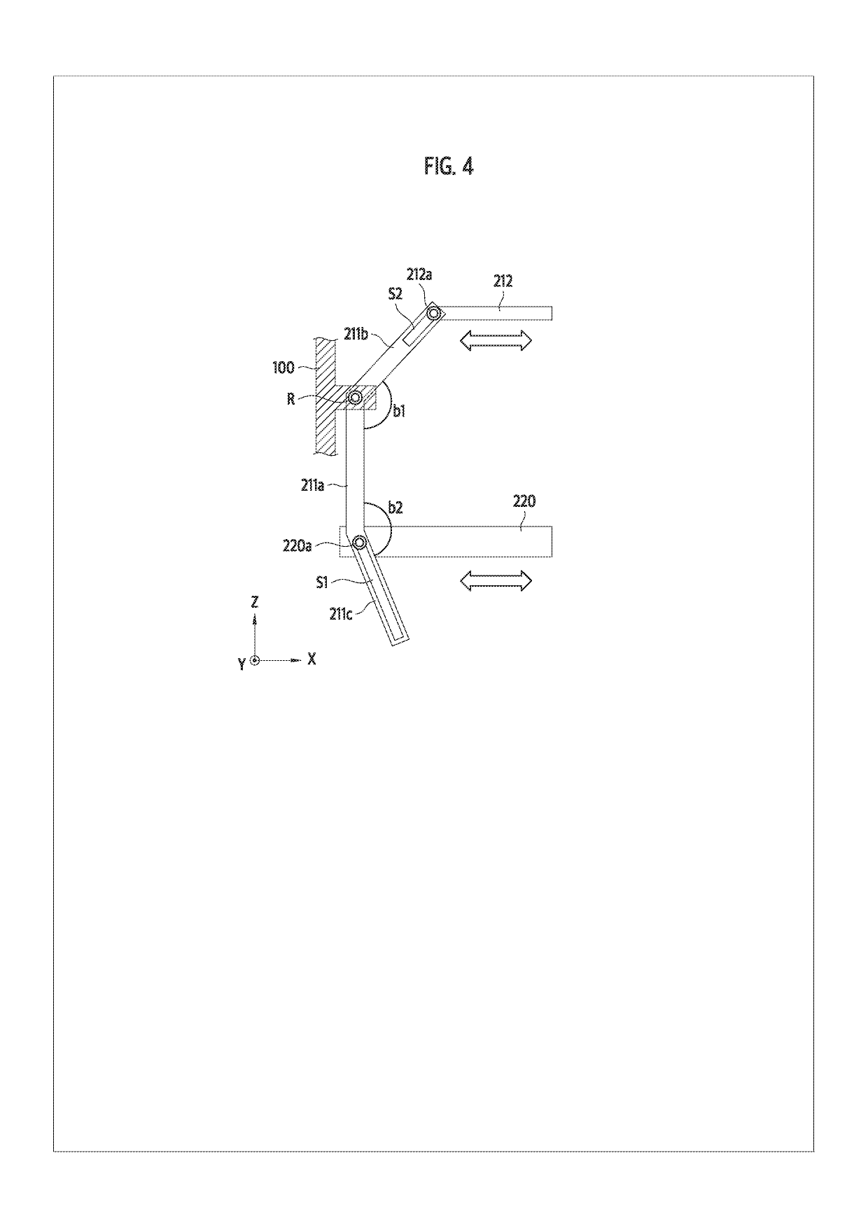

Referring to FIGS. 3 and 4 together, the link structure 210 may include the lever part 212 (e.g., lever) which moves in a sliding manner by receiving the external force from the pressurization part 323 and a link body part 211 (e.g., link body). The link body part 211 may be connected to each of the lever part 212 and the shelf part 220, rotate around the rotation shaft R connected to the container frame 100, and send the external force which has been applied to the lever part 212 to the shelf part 220.

In example embodiments, the lever part 212 may be disposed in parallel with the shelf part 220 in the container frame 100. For example, referring to FIGS. 3 and 4, the container frame 100 may include a vertical frame 110 for providing rigidity in a vertical direction (e.g., a Z-axis direction) and a first horizontal frame 121 and a second horizontal frame 122 connected to the vertical frame 110 and parallel to each other. The shelf part 220 may be supported to slide on the first horizontal frame 121 of the container frame 100. The lever part 212 may be supported to slide on the second horizontal frame 122, e.g., above the first horizontal frame 121.

In example embodiments, the lever part 212 may be configured to move in the sliding manner along the second horizontal frame 122 of the container frame 100 when the external force is applied from the pressurization part 323. For example, a guide rail (not illustrated) or a guide slot (not illustrated) extending in the horizontal direction (e.g., the X-axis direction) to guide movement of the lever part 212 may be disposed on or in the second horizontal frame 122, and the lever part 212 may be inserted into the guide rail (not illustrated) or the guide slot (not illustrated) and move in the sliding manner.

In example embodiments, the link body part 211 may be connected with each of the lever part 212 and the shelf part 220 and may be configured to move the shelf part 220 in the sliding manner by interlocking with motion of the lever part 212.

FIG. 4 is a reference diagram for describing the link structure 210 of the substrate storage system 1 according to example embodiments.

In example embodiments, the link body part 211 may include a first link body part 211a (e.g., a first link arm) extending from the rotation shaft R toward the shelf body part 220, a second link body part 211b (e.g., a second link arm) extending from the rotation shaft R toward the lever part 212, and a third link body part 211c (e.g., a third link arm) connected to an end of the first link body part 211a and forming a region of connection with the shelf part 220.

In example embodiments, a first slot S1 and a second slot S2 may be disposed at opposite ends of the link body part 211, respectively. A first connection part 220a (e.g., a first protrusion) in which the link body part 211 and the shelf part 220 are connected with (e.g., movably coupled with) each other may be movably coupled to the first slot S1. A second connection part 212a (e.g., a second protrusion) in which the link body part 211 and the lever part 212 are connected with (e.g., movably coupled with) each other may be movably coupled to the second slot S2.

In example embodiments, the first slot S1 may be disposed in the third link body part 211c. The first connection part 220a of the shelf part 220 may move in a sliding manner along the first slot S1 in a state of being inserted into the first slot S1. The first connection part 220a may be defined as a region of connection of the shelf part 220 with the link body part 211 and may be configured to smoothly move in the first slot S1. While the first connection part 220a of the shelf part 220 may move along the first slot S1 of the link body part 211 as such, movement of the shelf part 220 in a vertical direction (a Z-axis direction) is limited by the first horizontal frame 121 (of FIG. 3), and accordingly, rotation motion of the link body part 211 may be converted into sliding motion of the shelf part 220. In order to reduce friction between the first connection part 220a and the first slot S1, the first connection part 220a may further include a roller or a bearing that may move in a rolling manner along an inner peripheral surface of the first slot S1.

In example embodiments, the second slot S2 may be disposed in the second link body part 211b. The second connection part 212a of the lever part 212 may move in a sliding manner along the second slot S2 in a state of being inserted into the second slot S2. The second connection part 212a may be defined as a region of connection of the lever part 212 with the link body part 211 and may be configured to smoothly move in the second slot S2. While the second connection part 212a of the lever part 212 may move along the second slot S2 of the link body part 211 as such, movement of the lever part 212 in the vertical direction (the Z-axis direction) is limited by the second horizontal frame 122, and accordingly, sliding motion of the pressurization part 323 may be converted into the rotation motion of the link body part 211 via sliding motion of the lever part 212. As required, in order to reduce friction between the second connection part 212a and the second slot S2, the second connection part 212a may further include a roller or a bearing that may move in a rolling manner along an inner peripheral surface of the second slot S2.

In example embodiments, the link body part 211 may have a structure bent around the rotation shaft R. For example, referring to FIG. 4, the first link body part 211a and the second link body part 211b may extend away from the rotation shaft R in different directions from each other such that they are not collinear, and accordingly, the link body part 211 may have a structure bent so that an angle b1 between the first link body part 211a and the second link body part 211b is formed as an obtuse angle. Through the structure bent as such, the link body part 211 and the container frame 100 may be prevented from interfering with each other during the rotation motion of the link body part 211 in a narrow space in the container frame 100.

In addition, the link body part 211 may have a structure bent around a point of connection of the first link body part 211a and the third link body part 211c. For example, referring to FIG. 4, the first link body part 211a and the third link body part 211c may extend in different directions from each other such that they are not collinear, and accordingly, the link body part 211 may be formed as a structure bent so that an angle b2 between the first link body part 211a and the third link body part 211c is formed as an obtuse angle. As such, the link body part 211 may have a structure in which the second link body part 211b and the third link body part 211c extend from either end of the first link body part 211a in directions different from an extension direction (or a longitudinal direction) of the first link body part 211a. When the link body part 211 has such a bent structure, the link structure 210 may be effectively received in the narrow space in the container frame 100, and also, the shelf part 220 may travel a relatively longer distance in a sliding manner even if the lever part 212 travels a short distance in a sliding manner.

Furthermore, regarding the link structure 210 according to example embodiments, an interval (e.g., a distance) between the first connection part 220a and the rotation shaft R may be larger than an interval between the second connection part 212a and the rotation shaft R. For example, the first link body part 211a may extend to be longer than a maximum interval between the second connection part 212a and the rotation shaft R. Accordingly, in the link structure 210, a maximum rotation radius of the second connection part 212a around the rotation shaft R may be smaller than a minimum rotation radius of the first connection part 220a. Due to such a difference between radii, a range of sliding movement of the shelf part 220 which is interlocked with the lever part 212 through the link structure 210 may be larger than a range of sliding movement of the lever part 212. To correspond thereto, a length of the first slot S1 to which the first connection part 220a is connected may be formed to be longer than a length of the second slot S2 to which the second connection part 212a is connected.

In example embodiments, the shelf part 220 may be configured so that the substrate receiving container 20 is seated on and loaded onto an upper surface thereof and may be connected to the link body part 211 to be withdrawn to an outside of the container frame 100 or carried into an inside of the container frame 100 as the link body part 211 rotates.

In example embodiments, the shelf part 220 may be configured to move in the sliding manner along the first horizontal frame 121 of the container frame 100. For example, a guide rail (not illustrated) or a guide slot (not illustrated) extending in a horizontal direction (an X-axis direction) to guide movement of the shelf part 220 may be disposed on or in the first horizontal frame 121, and the shelf part 220 may be inserted into the guide rail (not illustrated) or the guide slot (not illustrated) and move in the sliding manner.

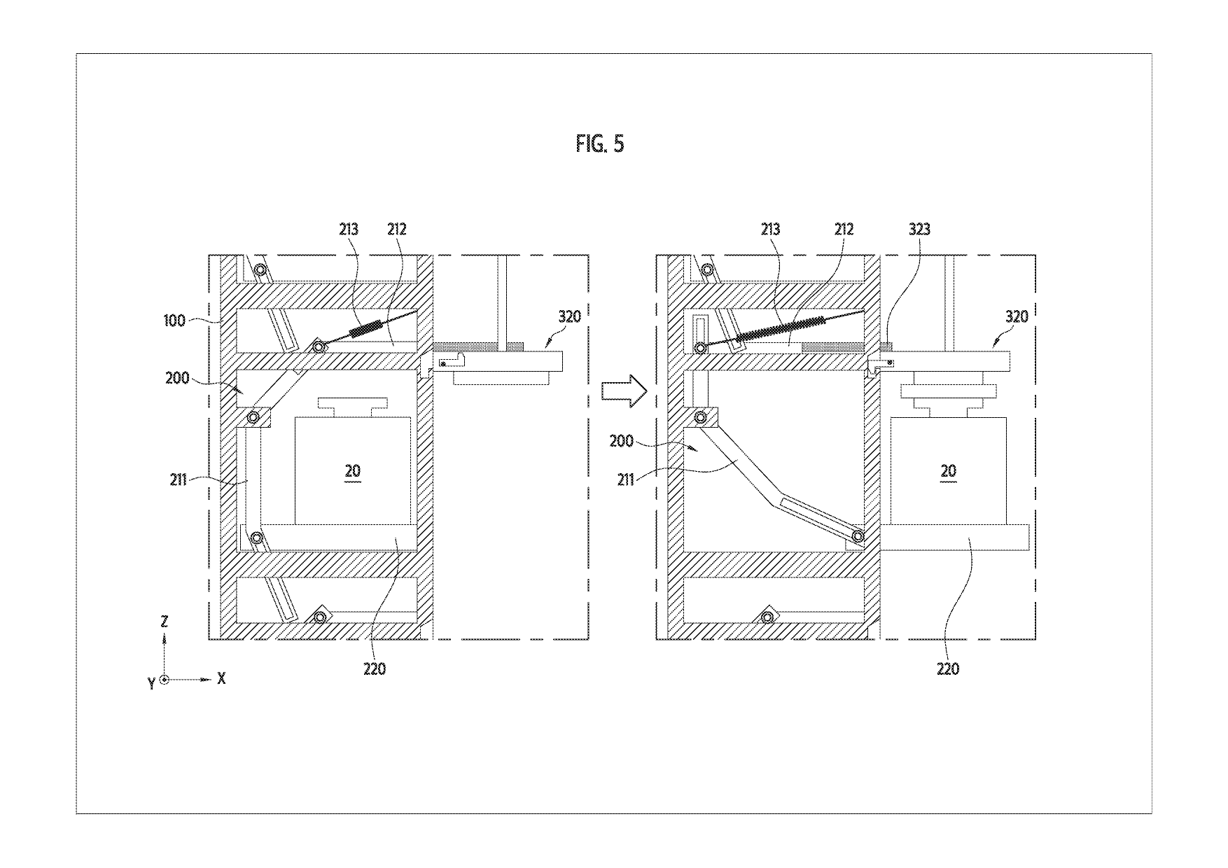

FIG. 5 is a reference diagram illustrating a state in which an elastic member 213 is connected to the link structure 210 of the substrate storage system 1 according to example embodiments.

Meanwhile, the container 10 may further include the elastic member 213 for returning the shelf part 220 to an initial position after the substrate receiving container 20 is loaded and unloaded. The elastic member 213 may be formed of, for example, a spring or an elastic band.

For example, the elastic member 213 may be connected between the link structure 210 (of FIG. 2) and the container frame 100. The elastic member 213 may return the lever part 212, the link body part 211, and the shelf part 220 to initial positions by applying elastic force to the lever part 212 or the link body part 211 when external force by the pressurization part 323 is removed. However, a detailed structure of the elastic member 213 or a position at which the elastic member 213 is disposed is not limited to an illustration in a drawing and may be applied without limitation so long as the elastic force for returning the shelf part 220 to the initial position is applied when the external force which is applied to the link structure 210 is removed.

Hereinafter, referring to FIGS. 3 and 6 through 9, a control method of the substrate storage system 1, which includes the transportation device 300 and the shelf assembly 200, is described according to example embodiments.

To begin with, referring to FIG. 3, the controller 500 sets a shelf assembly 200 that is to be unloaded with the substrate receiving container 20, among the plurality of shelf assemblies 200 which is disposed to the container 10, to be the target shelf assembly 200 and may control the traveling unit 310 to move to a position corresponding to a column in which the target shelf assembly 200 is disposed.

In example embodiments, in a state in which the traveling unit 310 (of FIG. 2) is arranged at the position corresponding to the column at which the target shelf assembly 200 (of FIG. 2) is disposed, the controller 500 (of FIG. 2) lowers the lifting unit 320 from an initial position (e.g., a position in a state of being pulled into or stored within the traveling unit 310) to a loading and unloading position next to the target assembly 200 by controlling the lifting unit 320 and the connection member 322. In this case, the loading and unloading position may be a position at which the pressurization part 323 of the lifting unit 320 faces the lever part 212 of the target shelf assembly 200.

In example embodiments, the transportation device 300 may further include a first sensor for sensing a position relative to the lever part 212. For example, the first sensor may be a position sensor disposed on the lifting unit 320. The first sensor may sense a relative position between the pressurization part 323 of the lifting unit 320 and the lever part 212 of the target shelf assembly 200, convert the relative position into first position information, and transmit the first position information to the controller 500. The controller 500 may identify a position of the lifting unit 320 based on the first position information and control the lifting unit 320 to stop at an appropriate position. However, control of lifting driving of the lifting unit 320 by the controller 500 is not limited to the above description. For example, the controller 500 may have access to height information regarding each of the shelf assemblies 200, and the lifting unit 320 may be controlled to descend by a predetermined height to correspond to the determined target shelf assembly 200.

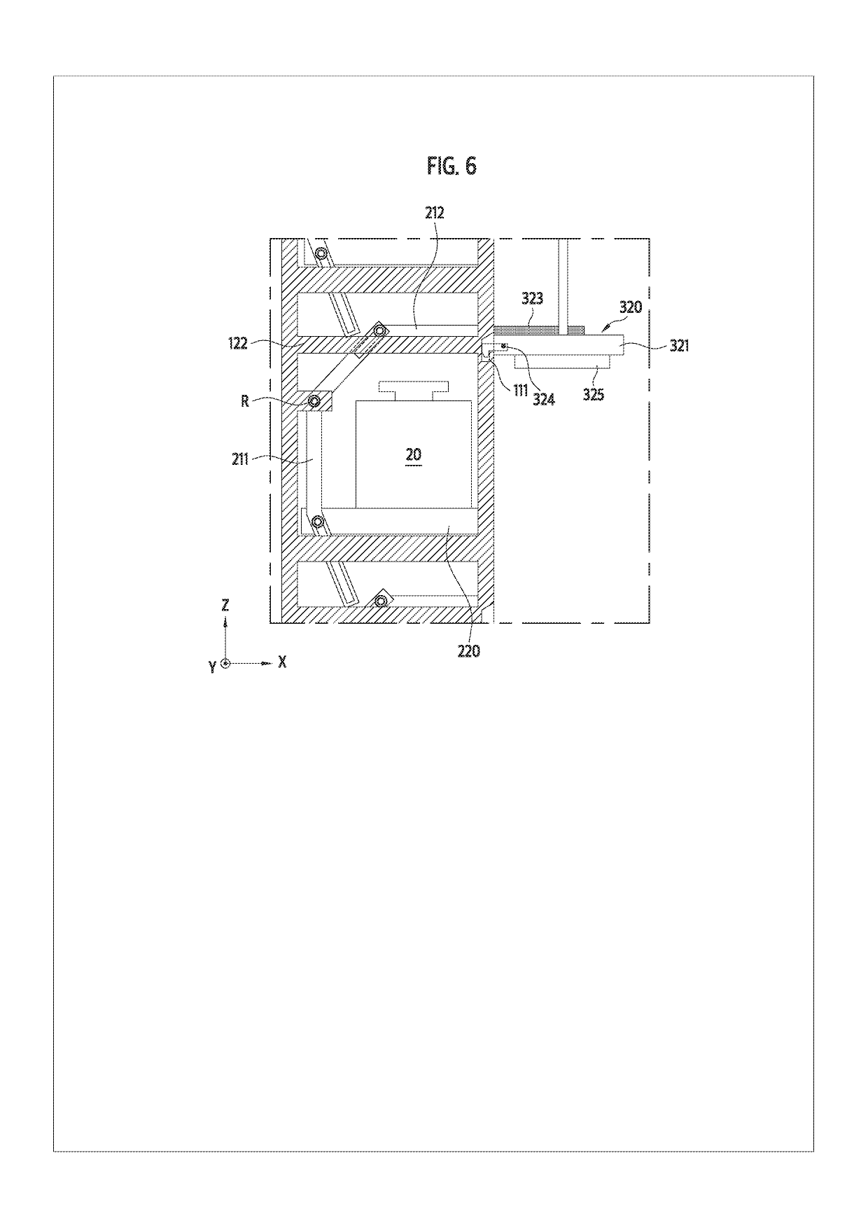

FIGS. 6 through 9 are reference diagrams for describing an operation of the substrate storage system 1 according to example embodiments.

Referring to FIG. 6, in a state in which the lifting unit 320 is arranged at a loading and unloading position, the controller 500 causes the position fixation part 324 to engage with the fixation groove 111 of the container frame 100 by rotating the fixation part 324. Accordingly, the lifting unit 320 may stably perform a subsequent task in a state of being fixed at the loading and unloading position. For example, the position fixation part 324 may be rotated by a motor and/or an actuator and the controller 500 may operate the motor and/or actuator to cause the position fixation part 324 to rotate.

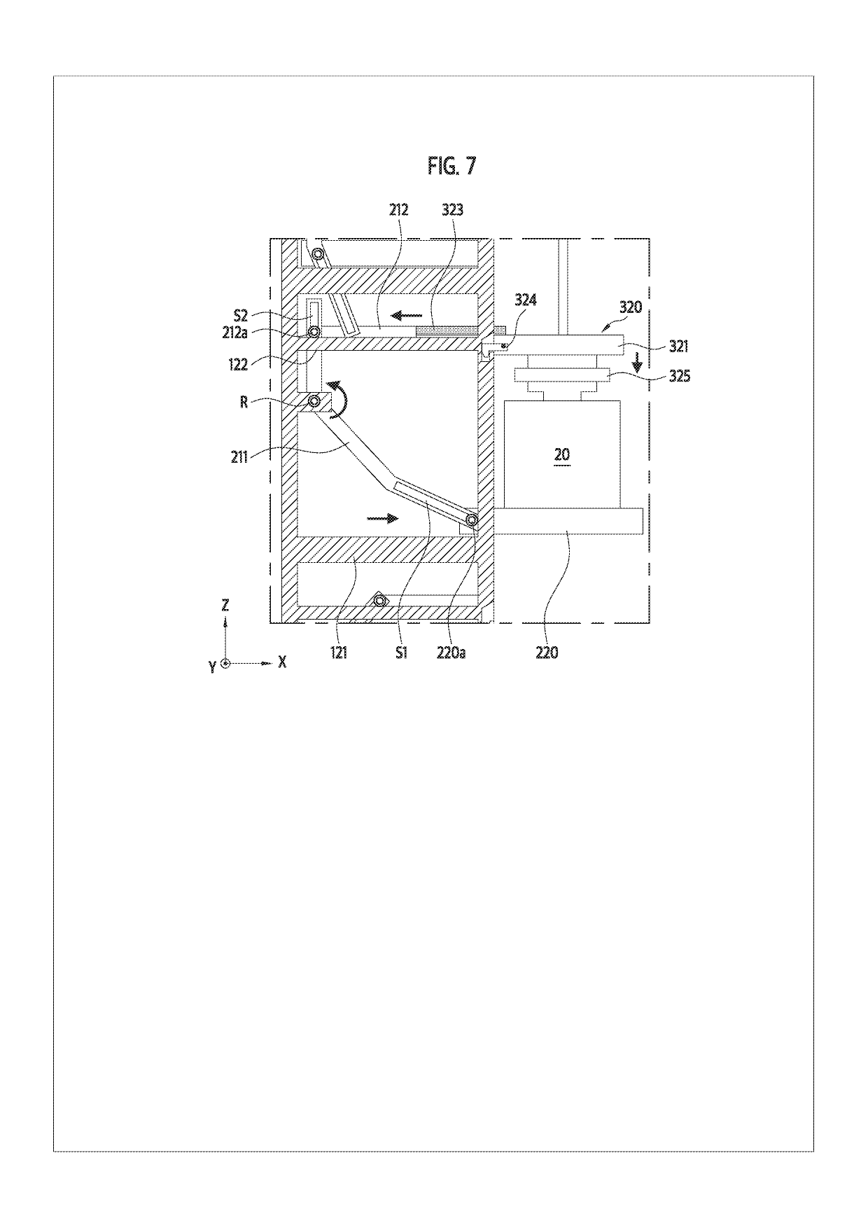

Referring to FIG. 7, the controller 500 withdraws the shelf part 220 to an outside of the container frame 100 by driving the pressurization part 323 which is disposed on the lifting unit 320. More specifically, the pressurization part 323 applies external force to the lever part 212 of the shelf assembly 200 by moving in a direction toward the shelf assembly 200, and the lever part 212 rotates the link body part 211 around the rotation shaft R while moving in a sliding manner, caused by the external force, in a movement direction of the pressurization part 323. Due to rotation of the link body part 211, the shelf part 220 which is connected to the first slot S1 of the link body part 211 is withdrawn to the outside of the container frame 100 by moving in a sliding manner in a direction opposite to a movement direction of the lever part 212. In a state in which the shelf part 220 has been withdrawn, the shelf part 220 and the substrate receiving container 20 which is loaded into the shelf part 220 may be positioned vertically below the lifting unit 320.

With continued reference to FIG. 7, in the state in which the shelf part 220 has been withdrawn, the grip part 325 which is disposed on the lifting unit 320 may descend from the lifting unit 320 and grip the substrate receiving container 20.

In example embodiments, the transportation device 300 may further include a second sensor for sensing a relative position of the grip part 325 of the lifting unit 320 with respect to the shelf part 220 (or with respect to the substrate receiving container 20 loaded into the shelf part 220). For example, the second sensor may be a position sensor disposed on the lifting unit 320. The second sensor may sense the relative position between the grip part 325 of the lifting unit 320 and the shelf part 220 of the target shelf assembly 200 (or the substrate receiving container 20 loaded into the shelf part 220), convert the relative position into second position information, and transmit the second position information to the controller 500. The controller 500 may determine, based on the second position information, whether the shelf part 220 is withdrawn to an appropriate position and whether the shelf part 220 is in position so that the grip part 325 may grip the substrate receiving container 20. Also, the controller 500 may adjust, based on the second position information, a position of the pressurization part 323 to appropriately change a position to which the shelf part 220 is withdrawn. According to such a control method, the grip part 325 of the transportation device 300 may accurately grip the substrate receiving container 20.

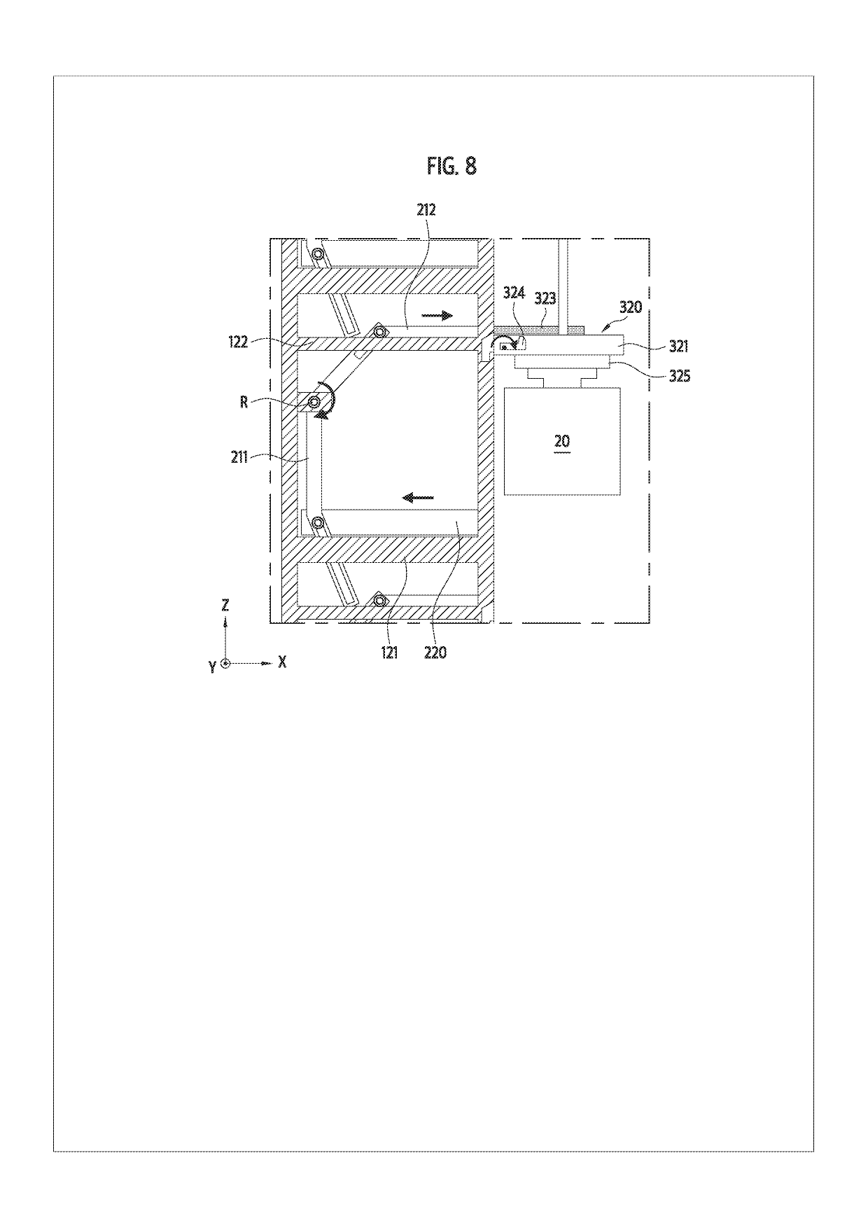

Referring to FIG. 8, in a state in which the grip part 325 grips the substrate receiving container 20, the controller 500 may control the pressurization part 323 and the position fixation part 324 to be driven in reverse order of the above-described order. That is, as the pressurization part 323 moves backward and returns to an original position thereof on the lifting unit 320, the lever part 212 may rotate the link body part 211 while returning back to an original position thereof with the external force applied to the lever part 212 being removed. Accordingly, the shelf part 220 may be carried into an inside of the container frame 100. When a backward movement operation of the pressurization part 323 is completed, the controller 500 separates the position fixation part 324 from the fixation groove 111 of the container frame 100 by reversely rotating the position fixation part 324. Accordingly, a position of the lifting unit 320 may be unfixed relative to the container frame 100.

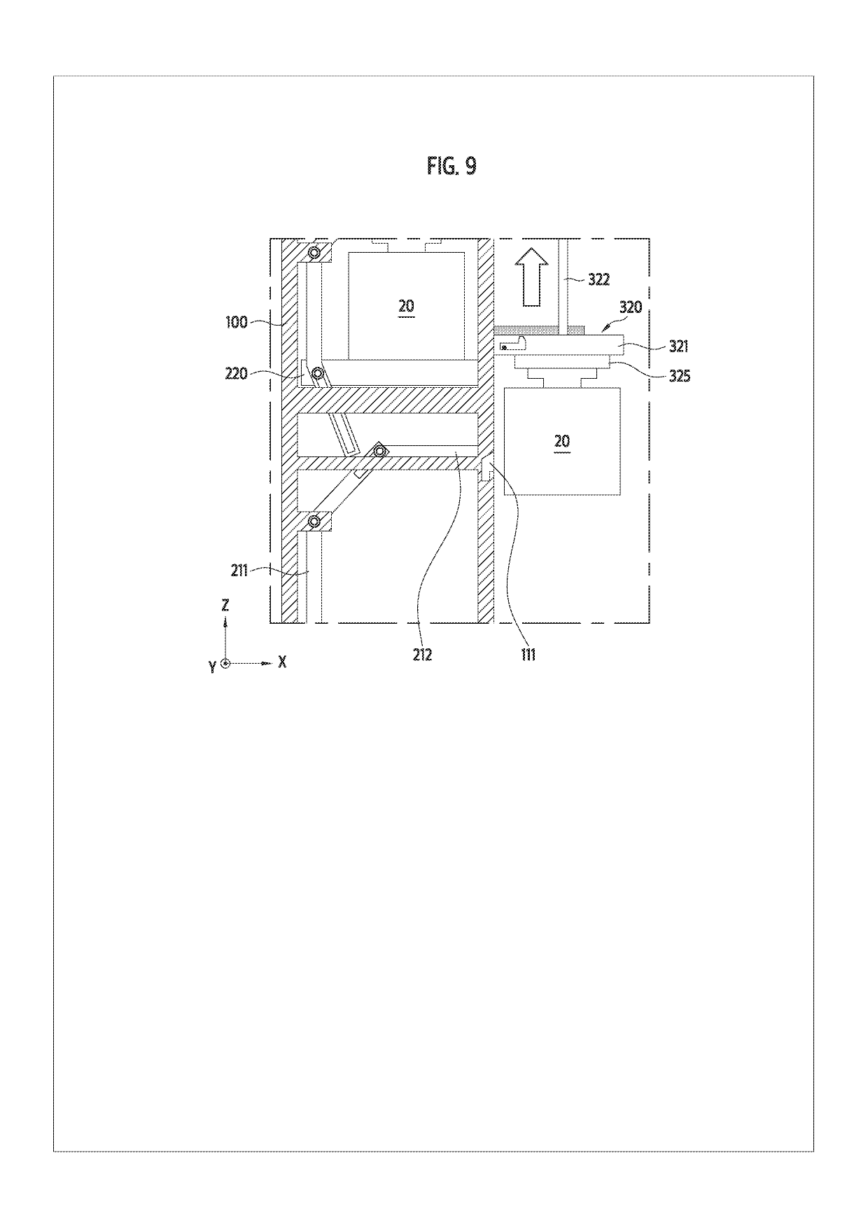

Referring to FIG. 9, in a state in which the position of the lifting unit 320 is unfixed, the controller 500 returns the lifting unit 320 to an initial position by controlling the lifting unit 320 and the connection member 322. In other words, the lifting unit 320 returns to the initial position by ascending toward the traveling unit 310.

Through such a process, the transportation device 300 may directly approach the target shelf assembly 200 among the plurality of shelf assemblies 200 which is loaded into the container 10 and may load and unload the substrate receiving container 20 into and from the target shelf assembly 200.

Accordingly, speed and efficiency of loading and unloading the substrate receiving container 20 may be largely increased when compared to a carrier storage equipment in the related art, which may have been loaded and unloaded with a substrate receiving container only through interface ports at specific positions. Since the transportation device 300 may individually approach each target shelf assembly 200 and directly perform a loading and unloading task, an additional process of moving a substrate receiving container from an interface port to a final loading position for the substrate receiving container may be omitted. Also, since many transportation devices 300 may simultaneously perform loading and unloading tasks for different shelf assemblies 200, a loading and unloading task speed may be increased. Therefore, operation efficiency of the substrate storage system 1 may be increased, and efficiency of an entire semiconductor manufacturing process may be also increased.

In addition, since an additional actuator and a control element for withdrawing the shelf part 220 may be omitted from the container 10 because a driving system (e.g., the pressurization part 323, the position fixation part 324, and the like) for withdrawing and carrying the shelf part 220 is instead disposed on the lifting unit 320 which directly approaches the shelf assembly 200, the substrate storage system 1 may be implemented with a simple structure at a low cost.

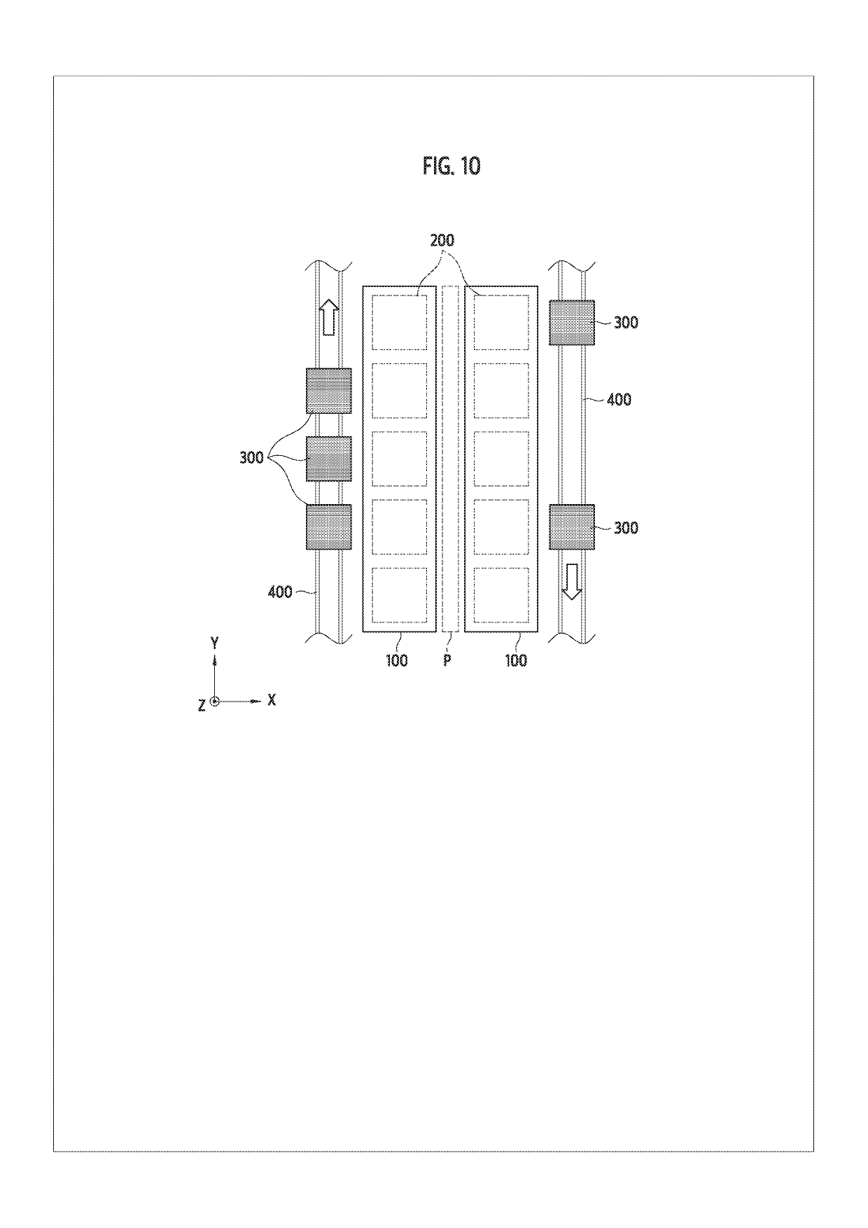

Furthermore, as described through FIG. 10, the substrate storage system 1 according to example embodiments may increase space efficiency in a semiconductor manufacture factory to which the substrate storage system 1 is disposed.

FIG. 10 is an example plan diagram illustrating the substrate storage system 1 according to example embodiments.

Since the substrate storage system 1 which is described in FIG. 10 includes all characteristics of the substrate storage system 1 which is described in FIGS. 1 through 9, redundant descriptions similar to those of FIGS. 1 through 9 may be omitted.

In example embodiments, the substrate storage system 1 may include a plurality of containers 10 each loaded with the plurality of shelf assemblies 200 and a plurality of transportation devices 300 for loading and unloading the substrate receiving container 20 into and from one of the plurality of shelf assemblies 200 while moving along the rail 400.

As described above through FIGS. 2 through 9, the transportation device 300 according to example embodiments may individually approach one of the plurality of shelf assemblies 200 and load and unload the substrate receiving container 20. Accordingly, while one transportation device 300 loads and unloads the substrate receiving container 20 into and from one of the plurality of shelf assemblies 200, another transportation device 300 may simultaneously load and unload a substrate receiving container 20 into and from another shelf assembly 200. As such, since multiple transportation devices 300 may freely perform loading and unloading tasks at positions individually targeted by the transportation devices 300, a task performance speed and task efficiency may be increased.

Also, in a carrier storage equipment in the related art, an additional transfer robot for transferring a substrate receiving container from an interface port to each storage space in the carrier storage equipment has been required. However, since each transportation device 300 directly performs a loading and unloading task for each individual shelf assembly 200 in the substrate storage system 1 according to example embodiments, such an additional transfer robot may be omitted. Accordingly, space efficiency may be improved by saving a space wasted on disposition of an existing transfer robot. For example, referring to FIG. 10, since a space P between the containers 10, which has been required for disposing an existing transfer robot, may be minimized, and since the plurality of containers 10 may be densely disposed, more containers 10 may be disposed in an equal area. Thus, space efficiency in a semiconductor manufacture factory may be increased, and overall storage efficiency in the semiconductor manufacture factory may be also increased.

The various example embodiments of the present disclosure have been described above in detail, but the scope of the present disclosure is not limited thereto. It will be apparent to those skilled in the art that various changes and modifications may be allowed within the scope of the technical spirit of the present disclosure. In addition, the above-described example embodiments may be implemented without a portion of elements thereof, and each of the example embodiments may be implemented in combination with another.

What is claimed is:

1. A substrate storage system comprising:
a shelf assembly configured to accommodate a substrate receiving container;
a container frame that supports the shelf assembly and includes an entrance corresponding to the shelf assembly; and
a transport configured to move along a rail disposed above the container frame, the transport being configured to load or unload the substrate receiving container into or from the shelf assembly,
wherein the shelf assembly comprises:
a link structure coupled to the container frame in a rotatable manner; and
a shelf that is connected to the link structure and is configured to accommodate the substrate receiving container,
wherein the transport comprises:
a vehicle movably coupled to the rail;
a lift disposed below the vehicle and configured to ascend and descend in a vertical direction; and
a pressing arm disposed on the lift and configured to apply an external force to the link structure by moving in a direction toward the shelf assembly, and
wherein the shelf is configured to move through the entrance of the container frame by moving as the link structure rotates, the rotation of the link structure being caused by the external force applied by the pressing arm.

2. The substrate storage system of claim 1, wherein the link structure comprises:
a lever disposed in parallel with the shelf and configured to move by receiving the external force from the pressing arm; and
a link body connected to the lever and the shelf and configured to transmit the external force from the lever to the shelf while rotating around a rotation shaft connected to the container frame.

3. The substrate storage system of claim 2, wherein the lever and the shelf are configured to move in directions opposite to each other by the external force applied by the pressing arm.

4. The substrate storage system of claim 2, wherein the link structure further comprises:
a first protrusion by which the link body and the shelf are connected with each other; and
a second protrusion by which the link body and the lever are connected with each other,
wherein a distance between the first protrusion and the rotation shaft is larger than a distance between the second protrusion and the rotation shaft.

5. The substrate storage system of claim 4, wherein the first protrusion is movably coupled to a first slot provided at an end of the link body, and
wherein the second protrusion is movably coupled to a second slot provided at another end of the link body.

6. The substrate storage system of claim 2,
wherein the link body comprises:
a first link arm extended from the rotation shaft toward the shelf; and
a second link arm extended from the rotation shaft toward the lever, and
wherein an angle between the first link arm and the second link arm is a first obtuse angle.

7. The substrate storage system of claim 6, wherein the link body further comprises a third link arm extended from an end of the first link arm, the third link arm comprising a slot to which the shelf is movably coupled, and
wherein an angle between the first link arm and the third link arm is a second obtuse angle.

8. The substrate storage system of claim 1,. the shelf is positioned vertically below the lift when withdrawn through the entrance of the container frame after the link has rotated.

9. The substrate storage system of claim 1, wherein the transport further comprises a latch coupled to the lift in a rotatable manner and configured to fix a position of the lift by engaging with the container frame.

10. The substrate storage system of claim 9, wherein the container frame comprises:
a horizontal frame supporting the shelf; and
a vertical frame supporting the horizontal frame and comprising a fixation groove with which the latch is configured to engage.

11. The substrate storage system of claim 10, wherein the fixation groove is disposed in the vertical frame,
wherein the fixation groove is one of a plurality of fixation grooves and the entrance is one of a plurality of entrances, and
wherein each of the plurality of fixation grooves corresponds to a respective entrance of the plurality of entrances.

12. The substrate storage system of claim 1, wherein the transport further comprises a grip disposed below the lift and configured to grip the substrate receiving container.

13. A control method of a substrate storage system, the control method comprising:
lowering, from an initial position to a position next to a target shelf assembly selected from a plurality of shelf assemblies disposed in a container frame, a lift provided on a transport, the transport being configured to transfer a substrate receiving container to or from the container frame;
withdrawing a shelf included in the target shelf assembly to an outside of the container frame by application, by a pressing arm disposed on the lift, of an external force to a link structure included in the target shelf assembly; and
loading or unloading, with a grip connected to the lift, the substrate receiving container into or from the shelf.

14. The control method of claim 13, further comprising fixing a position of the lift using a latch, the latch being coupled to the lift in a rotatable manner, by causing the latch to be caught in a fixation groove provided in the container frame.

15. The control method of claim 14, further comprising causing the shelf of the target shelf assembly to move into an inside of the container frame by backward movement of the pressing arm after the loading or unloading of the substrate receiving container is completed.

16. The control method of claim 15, further comprising:
unfixing the position of the lift by causing the latch to be separated from the fixation groove after the causing of the shelf to move into the inside of the container frame is completed; and
returning the lift to the initial position.

17. A substrate storage system comprising:
a container in which a plurality of shelf assemblies are arranged in a plurality of rows and columns, each of the plurality of shelf assemblies being configured to accommodate a substrate receiving container; and
a transport configured to move alongside the container and configured to load and unload the substrate receiving container into and from a target shelf assembly selected from the plurality of shelf assemblies,
wherein the transport comprises:
a vehicle configured to move in a direction parallel to a row formed by the plurality of shelf assemblies;
a lift connected with the vehicle and configured to move in a direction parallel to a column formed by the plurality of shelf assemblies;
a latch disposed on the lift and configured to fix a position of the lift by engaging with the container; and
a pressing arm disposed on the lift and configured to move a shelf of the target shelf assembly to an outside of the container by moving in a direction toward the target shelf assembly.

18. The substrate storage system of claim 17, wherein the target shelf assembly comprises:
a lever configured to move in a sliding manner by receiving an external force from the pressing arm; and
a link body connected to the lever and the shelf and configured to move the shelf by interlocking with movement of the lever.

19. The substrate storage system of claim 18,
wherein the link body comprises:
a first slot to which the shelf is movably coupled; and
a second slot to which the lever is movably coupled, and
wherein a length of the first slot is longer than a length of the second slot.

20. The substrate storage system of claim 18, further comprising a controller configured to control the transport,
wherein the controller is configured to control the pressing arm to move to apply the external force to the lever in a state in which the latch engages with the container.
